(19) United States
(12) Patent Application Publication
(10) Pub. No.: US 2021/0080783 A1
(43) Pub. Date: Mar. 18, 2021

(54) POLARIZATION GRATING HAVING A LIGHT-SHIELDING LAYER, MANUFACTURING METHOD FOR THE SAME AND DISPLAY PANEL FOR THE SAME

(71) Applicant: Wuhan China Star Optoelectronics Technology Co., Ltd, Wuhan, Hubei (CN)

(72) Inventor: Yuan YAN, Wuhan, Hubei (CN)

(21) Appl. No.: 16/080,238

(22) PCT Filed: May 2, 2018
(86) PCT No.: PCT/CN2018/085281

§ 371 Date: Aug. 27, 2018

(30) Foreign Application Priority Data
Mar. 30, 2018 (CN) 201810290907.4

(51) Int. Cl. G02F 1/1335; G02B 5/18; G02B 5/30; C23F 1/02; G03F 7/30

(52) U.S. Cl. CPC G02F 1/133548; G02B 5/1814; G02B 5/1857; G03F 7/30; G02F 1/133512; G02F 1/133504; C23F 1/02; G02B 5/3058

(57) ABSTRACT

A polarization grating having a light-shielding layer and a manufacturing method for the same are disclosed. The method includes steps of: forming a metal layer on a substrate, forming a shielding layer on the metal layer, wherein the shielding layer includes a light-shielding pattern layer and a polarization grating pattern layer and etching the metal layer 20 according to the shielding layer to form a polarization grating, wherein the polarization grating includes a polarization section and a light-shielding section directly connected to the polarization section. The present invention improves the compactness of the display panel.

### FIELD OF THE INVENTION

The present invention relates to a display technology field, and more particularly to a polarization grating having a light-shielding layer, a manufacturing method for the same and a display panel for the same.

### BACKGROUND OF THE INVENTION

As the communication interface between people and information, the liquid crystal display is the current mainstream display method. It has the advantages of high space utilization, low power consumption, no radiation, and low electromagnetic interference, and is widely applied in information communication tools such as televisions, mobile phones, and tablet computers.

The liquid crystal display is a passive-type display device that adjusts the arrangement state of liquid crystal molecules through an electric field in order to realize luminous flux modulation. The most widely applied liquid crystal display device currently is a twisted nematic liquid crystal display. The twisted nematic liquid crystal display sandwiches liquid crystal molecules between two glass plates and arranges the molecules in parallel along the glass surface. The molecules continuously twist between the two glass plates at a certain angle. The twisted nematic liquid crystal display is equipped with a polarizer on the outside. When a voltage is applied to the display region, the arrangement state of the liquid crystal molecules will be changed, and the purpose of display will be achieved by modulating the luminous flux.

In order to improve the brightness and darkness contrast and luminous flux of the liquid crystal display, a polarizer is generally disposed directly on the array substrate. Besides, in order to further improve the contrast of the liquid crystal display, a light-shielding structure is provided under the thin-film transistor of the array substrate to reduce excitation of the semiconductor layer by the external light source and avoid display failure. However, in the prior art, the grating and the light-shielding structure are two independent layers, which reduces the structural compactness of the display panel.

### SUMMARY OF THE INVENTION

In order to solve the deficiencies of the above prior art, the present invention aims to provide a polarization grating that improves the compactness of the display panel, a manufacturing method thereof, and a display panel for the same.

In order to solve achieve the above purpose, the present invention adopts following solution: a manufacturing method for a polarization grating having a light-shielding layer, comprising: forming a metal layer on a substrate; forming a shielding layer on the metal layer, wherein the shielding layer includes a light-shielding pattern layer and a polarization grating pattern layer; and etching the metal layer 20 according to the shielding layer to form a polarization grating, wherein the polarization grating includes a polarization section and a light-shielding section directly connected to the polarization section.

Wherein the light-shielding pattern layer and the polarization grating pattern layer are formed in a same process.

Wherein the step of forming a shielding layer on the metal layer comprises steps of: forming an imprint adhesive layer on the metal layer; and using an imprint template corresponding to the light-shielding pattern layer and the polarization grating pattern layer to perform a transfer process to the imprint adhesive layer in order to form the shielding layer.

Wherein the step of forming a shielding layer on the metal layer comprises steps of: forming a photoresist layer on the metal layer; and using a mask plate corresponding to the shielding layer to utilize a lithography process to the photoresist layer in order to form the shielding layer.

Wherein the light-shielding section includes multiple light-shielding blocks arranged as a matrix, at least one first grating bar extending along a column direction is disposed between adjacent two columns of the light-shielding blocks, at least one second grating bar extending along the column direction is disposed between two adjacent light-shielding blocks in each column of the light-shielding blocks; and the polarization section includes multiple first grating bars and multiple second grating bars.

The present invention also discloses a polarization grating having a light-shielding layer, comprising: a polarization section; and a light-shielding section directly connected to the polarization section.

Wherein the light-shielding section includes multiple light-shielding blocks arranged as a matrix, at least one first grating bar extending along a column direction is disposed between adjacent two columns of the light-shielding blocks, and at least one second grating bar extending along the column direction is disposed between two adjacent light-shielding blocks in each column of the light-shielding blocks.

Wherein the light-shielding section includes multiple light-shielding blocks 21a arranged as a matrix, and the polarization section includes multiple grating bars arranged separately; and each light-shielding block is located on at least one of the grating bars.

Wherein the light-shielding section and the polarization section are formed in a same process.

Wherein the light-shielding block has a rectangular shape, and the light-shielding section and the polarization section are made of a metal material.

Wherein a thickness of the polarization section is 20 nm˜3000 nm, a width of the grating bar of the polarization section is 30 nm˜100 nm, and a gap between adjacent two grating bars is 30 nim-100 nm.

The present invention also provides an array substrate, comprising a polarization grating having a light-shielding layer using a manufacturing method described in anyone above, or comprising a polarization grating having a light-shielding layer in anyone above.

The present invention also provides a display panel, comprising: an array substrate and a polarization grating having a light-shielding layer; wherein the polarization grating having a light-shielding layer is disposed on the array substrate, the light-shielding section is right opposite to a thin-film transistor of the array substrate; wherein the polarization grating having a light-shielding layer is a polarization grating having a light-shielding layer manufactured by the manufacturing method described in anyone above, or comprising a polarization grating having a light-shielding layer described in anyone above.

The present invention also provides a display module, comprising a polarization grating having a light-shielding layer using a manufacturing method described in anyone above, or comprising a polarization grating having a light-shielding layer in anyone above.

The present invention also provides a terminal, comprising a polarization grating having a light-shielding layer using a manufacturing method described in anyone above, or comprising a polarization grating having a light-shielding layer in anyone above.

Beneficial effects: The method for fabricating a polarization grating having a light-shielding layer, the polarization grating with a light-shielding layer, the array substrate, the display panel, the display module, and the terminal disclosed in the present invention, the polarization section and the light-shielding section are fabricated on one component, which improves the compactness of the structure of the display panel.

### BRIEF DESCRIPTION OF THE DRAWINGS

FIG. 1A to FIG. 1D are process diagrams of a polarization grating having a light-shielding layer according to a first embodiment of the present invention.

FIG. 2A to FIG. 2C are process diagrams of a shielding layer according to a first embodiment of the present invention.

FIG. 3A to FIG. 3C are process diagrams of a shielding layer according to a second embodiment of the present invention.

FIG. 4 is a top view of a polarization grating having a light-shielding layer according to a third embodiment of the present invention.

FIG. 5 is a cross-sectional view of a polarization grating having a light-shielding layer according to a fourth embodiment of the present invention,

FIG. 6 is a cross-sectional view of a display panel according to a fifth embodiment of the present invention.

FIG. 7 is a cross-sectional view of another display panel according to a fifth embodiment of the present invention.

### DETAILED DESCRIPTION OF PREFERRED EMBODIMENTS

To make the objectives, technical solutions, and advantages of the present invention clearer, the following further describes the present invention in detail with reference to the accompanying drawings and embodiments. It should be understood that the specific embodiments described herein are only used to explain the present invention and are not used to limit the present invention.

### Embodiment 1

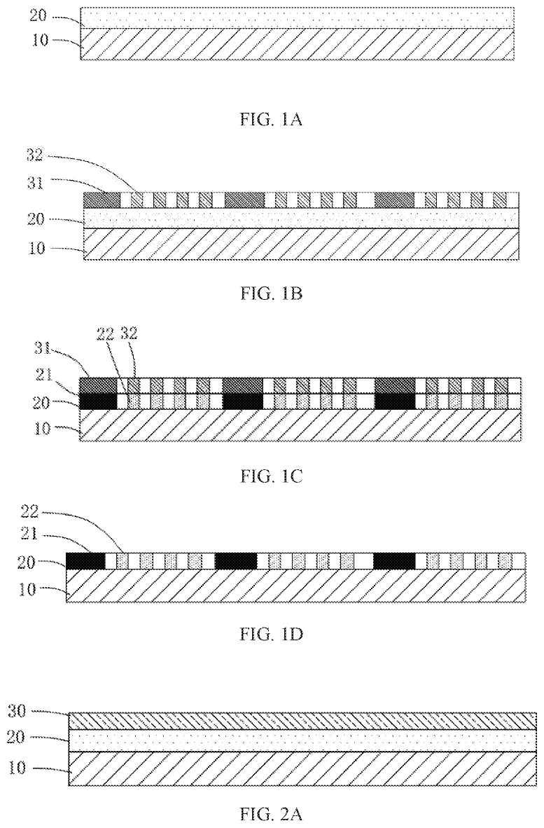

FIGS. 1A to 1D show a process diagram of a polarization grating having a light-shielding layer according to the present invention. The manufacturing method for the polarization grating having the light-shielding layer includes a step 1 to a step 4:

Step 1: referring to FIG. 1A, forming a metal layer 20 on a substrate 10,

As a preferred embodiment, the substrate 10 is preferably a glass substrate, the material of the metal layer 20 is selected as molybdenum; and forming a molybdenum film on a surface of the substrate 10 by a deposition process. Of course, in other embodiments, the material of the metal layer 20 may also be selected as aluminum, and the metal layer 20 must be ensured to have a good light-shielding property in material selection.

Step 2: referring to FIG. 1B, forming a shielding layer on the metal layer 20. Wherein the shielding layer includes a light-shielding pattern layer 31 and a polarization grating pattern layer 32.

Wherein, the light-shielding pattern layer 31 and the polarization grating pattern layer 32 are formed in the same process. As a preferred embodiment, the step 2 specifically includes a step 21 to a step 23.

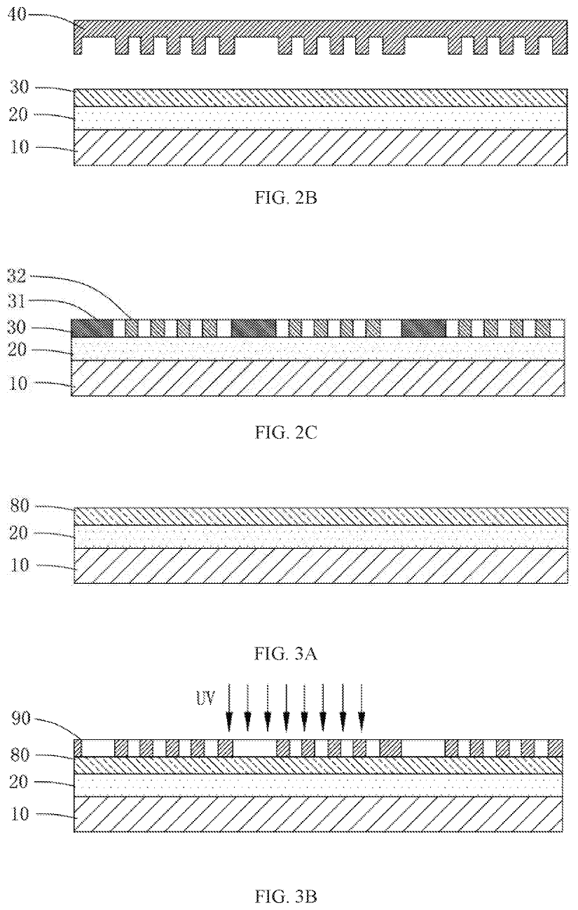

Specifically, in the step 21: referring to FIG. 2A, forming an imprint adhesive layer 30 on the metal layer 20.

Furthermore, the material of the imprint adhesive layer 30 is preferably polyimide (PI), and the polyimide is uniformly coated on the metal layer 20 by coating to form the imprint adhesive layer 30. Of course, in another embodiment, the material of the embossed adhesive layer 30 may also be selected as other materials. In addition, a spin-coater may be used to coat the imprint adhesive layer 30 on the metal layer 20.

Step 22: referring to FIG. 2B, using an imprint template 40 corresponding to the light-shielding pattern layer 31 and the polarization grating pattern layer 32 to perform a transfer process to the imprint adhesive layer 30 in order to form the shielding layer.

Specifically, the imprint template 40 is provided with a groove structure corresponding to the light-shielding pattern layer 31 and a concavo-convex structure corresponding to the polarization grating pattern layer 32. Further, after the imprint template 40 is aligned with the imprint adhesive layer 30, the imprint adhesive is directly applied with a force so that a portion of the imprint adhesive layer 30 enters into the groove structure, and the other portion of the imprint adhesive layer 30 enters into the concavo-convex structure, and the imprint template 40 abuts the metal layer 20 so that the imprint adhesive layer 30 is imprinted into the groove structure and the concavo-convex structure without excess residual layer.

Step 23: referring to FIG. 20, peeling off the imprint template 40.

Specifically, after the imprint template 40 is imprinted on the imprint adhesive layer 30, curing the imprint adhesive layer 30 so that the light-shielding pattern layer 31 and the polarization grating pattern layer 32 are fixed and formed on the imprint adhesive layer 30. Wherein, the ultraviolet light is preferably irradiated onto the imprint adhesive layer 30 to cure the light-shielding pattern layer 31 and the polarization grating pattern layer 32. After curing, the imprint template 40 is peeled from the imprint adhesive layer 30.

Of course, in other embodiments, the imprint template 40 may also be a cylinder-shaped template. The sidewall of the imprint template 40 is provided with a groove structure corresponding to the light-shielding pattern layer 31 and a concave-convex structure corresponding to the polarization grating pattern layer 32. The imprint adhesive layer 30 is imprinted in a roll-to-roll manner to form the light-shielding pattern layer 31 and the polarization grating pattern layer 32 on the imprint adhesive layer 30. In this way, the shielding layer can be simultaneously formed by one process.

Step 3: referring to FIG. 1C, etching the metal layer 20 according to the shielding layer to form a polarization grating, wherein the polarization grating includes a polarization section 22 and a light-shielding section 21 directly connected to the polarization section 22. In this way, the polarization grating can be formed at one time.

Specifically, a dry etching process is preferably used to etch the metal layer 20 with the shielding layer in order to form the polarization grating on the metal layer 20. The polarization grating includes the polarization section 22 and the light-shielding section 21 directly connected to the polarization section 22. Alternatively, in a top view, the grating bars of the polarization section 22 and the light-shielding blocks of the light-shielding section 21 are arranged separately in the horizontal direction.

Furthermore, thicknesses of the light-shielding section 21 and the polarization section 22 are the same, which ensures that the overall structure of the light-shielding section 21 and the polarization section 22 is more even. The polarization section 22 functions as a polarizer. The light-shielding section 21 and the polarization section 22 convert a natural light passing through into a polarized light to better regulate a light flux.

Specifically, as shown in FIG. 4, the polarization section 22 includes multiple first grating bars 22a and multiple second grating bars 22 b, and the light-shielding section 21 includes multiple light-shielding blocks 21a arranged as a matrix. At least one first grating bar 22a extending along a column direction is disposed between adjacent two columns of the light-shielding blocks 21. At least one second grating bar 22b extending along the column direction is disposed between two adjacent light-shielding blocks 21a in each column of the light-shielding blocks 21. The light-shielding section 21 is used for blocking a backlight below the array substrate to irradiate a thin-film transistor on the array substrate so as to prevent the backlight from being irradiated to a semiconductor layer of the thin-film transistor and prevent the light from affecting the conductivity of the semiconductor layer. The polarization section 22 corresponds to the pixel electrode above the array substrate and converts the light from the backlight into a polarized light to improve the display contrast.

Furthermore, a thickness of the polarization section 22 is in a range of 20 nm˜3000 nm, a width of the grating bar of the polarization section 22 is 30 nm˜100 nm, and a gap between adjacent two grating bars is 30 nm˜100 nm.

Step 4: referring to FIG. 10, peeling off the shielding layer.

Specifically, using a photoresist stripping machine to peel the shielding layer from the metal layer 20.

According to the manufacturing method of the polarization grating with the light shielding layer disclosed in the present invention, the polarization section and the light-shielding section are fabricated on one component, and the compactness of the structure of the display panel is improved. The present invention manufactures the polarization grating and the light-shielding layer simultaneously, which can reduce the number of process steps and reduce the production cost. In addition, the light-shielding layer and the polarization grating are located on the same film layer, so that the overall thickness of the array substrate is smaller.

### Embodiment 2

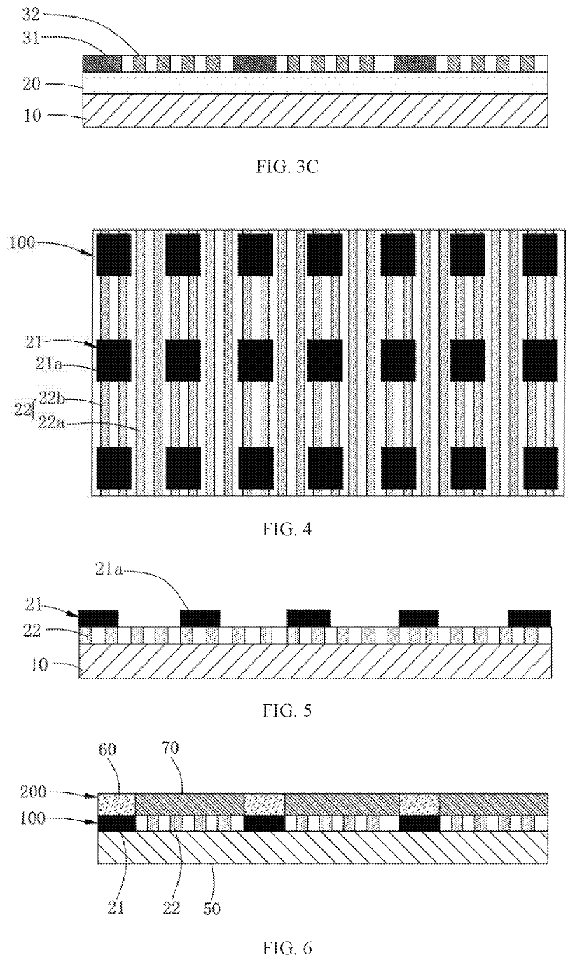

FIG. 3A to FIG. 3B illustrate a process diagram of a shielding layer according to a second embodiment of the present invention. The specific steps of forming the shielding layer on the metal layer 20 incudes follow steps:

Step 24: referring to FIG. 3A, forming a photoresist layer 80 on the metal layer 20.

Specifically, using a coater to coat a photosensitive material on the metal layer 20 in order to form the photoresist layer 80.

Step 25: referring to FIG. 3B and FIG. 3C, using a mask plate 90 corresponding to the shielding layer to utilize a lithography process to the photoresist layer 80 in order to form the shielding layer.

Specifically, a mask plate 90 having a pattern corresponding to the shielding layer is disposed on the photoresist layer 80, the photoresist layer 80 is exposed, the exposed photoresist layer 80 is then developed, and the developer is removed to form the photoresist layer 80. In this way, the shielding layer can be formed by one mask plate, and then the light-shielding section 21 and the polarization section 22 can be formed by one etching of the shielding layer, and the polarization grating can be manufactured while the shielding layer is manufactured, which reduces the number of process steps and reduces the production cost. In addition, the light-shielding layer and the polarization grating are located on the same film layer, so that the overall thickness of the array substrate is smaller.

### Embodiment 3

As shown in FIG. 4, a third embodiment of the present invention provides a polarization grating with a light-shielding layer. The polarization grating 100 with a light-shielding layer includes a light-shielding section 21 for shielding a thin-film transistor on an array substrate and a polarization section 22 located in the same layer as the light-shielding section 21.

Specifically, as shown in FIG. 4, the polarization section 22 includes multiple first grating bars 22a and multiple second grating bars 22b, and the light-shielding section 21 includes multiple light-shielding blocks 21a arranged as a matrix. At least one first grating bars 22a extending along a column direction is disposed between adjacent two columns of the light-shielding blocks 21. At least one second grating bar 22b extending along the column direction is disposed between two adjacent light-shielding blocks 21a in each column of the light-shielding blocks 21. The light-shielding section 21 is used for blocking a backlight below the array substrate to irradiate a thin-film transistor on the array substrate so as to prevent the backlight from being irradiated to a semiconductor layer of the thin-film transistor and prevent the light from affecting the conductivity of the semiconductor layer. The polarization section 22 corresponds to the pixel electrode above the array substrate and converts the light from the backlight into a polarized light to improve the display contrast. In this way, the polarization section 22 and the light-shielding section 21 are fabricated on one component, and the compactness of the structure of the display panel is improved.

Furthermore, the light-shielding section 21 and the polarization section 22 are formed in the same process, and the light-shielding section 21 and the polarization section 22 are made of a metal material. The light-shielding block 21a has a rectangular shape. A thickness of the polarization section 22 is in a range of 20 nm˜3000 nm, a width of the grating bar of the polarization section 22 is 30 nm˜100 nm, and a gap between adjacent two grating bars is 30 nm˜100 nm.

### Embodiment 4

As shown in FIG. 5, the difference between the polarization grating 100 with a light-shielding layer in the fourth embodiment of the present invention and the third embodiment is that the polarization grating 100 includes a polarization section 22 and a light-shielding section 21 disposed on the polarization section 22. Wherein the light-shielding section 21 includes multiple light-shielding blocks 21a arranged as a matrix, and the polarization section 22 includes multiple grating bars arranged separately, and each light-shielding block 21a is located on at least one of the grating bars. In this way, the polarization section 22 and the light-shielding section 21 are fabricated on one component, and the compactness of the structure of the display panel is improved.

### Embodiment 5

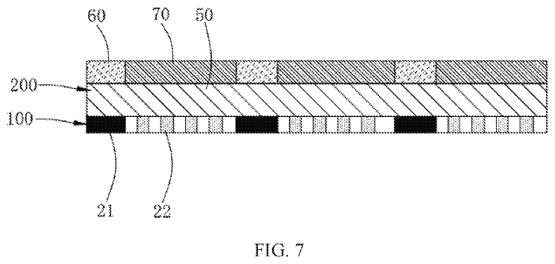

As shown in FIG. 6, a fifth embodiment of the present invention provides a display panel. In this embodiment, the display panel is an LCD panel. Of course, the type of the display panel is not limited thereto. The display panel includes an array substrate 200 and the above-mentioned polarization grating 100 having a light-shielding layer. The polarization grating 100 having a light-shielding layer is disposed on a base substrate 50 of the array substrate 200. The light-shielding section 21 is right opposite to a thin-film transistor 60 of the array substrate 200. The polarization section 22 is right opposite the pixel electrode 70 of the array substrate 200. In this way, the light-shielding section 21 can block the light emitted from the backlight to the thin-film transistor 60 and prevent the light from affecting the conductivity of the semiconductor layer. Through the polarization section 22, a natural light emitted from the backlight source can be converted into a polarized light and then be incident on the pixel electrode 70. No additional polarizer is required, thereby reducing the cost and reducing the thickness of the array substrate 200.

Here, as shown in FIG. 6, the polarization grating 100 having the light-shielding layer is disposed on a surface of the base substrate 50 facing toward the thin-film transistor 60. Of course, in other embodiments, as shown in FIG. 7, the polarization grating 100 having the light-shielding layer is disposed on the surface of the base substrate 50 facing away from the thin-film transistor 60.

### Example 6

A sixth embodiment of the present invention provides an array substrate including the polarization grating 100 described above. In this embodiment, the array substrate may be applied to an LCD panel. Of course, the use of the array substrate is not limited thereto. Thus, the polarization section 22 and the light-shielding section 21 are fabricated on one component, and the compactness of the structure of the display panel is improved.

### Example 7

A seventh embodiment of the present invention provides a display module. In this embodiment, the display module includes an LCD panel and a backlight module. The LCD panel includes the polarization grating 100 described above. Of course, the structure of the display module is not limited thereto. Thus, the polarization section 22 and the light-shielding section 21 are fabricated on one component, and the compactness of the structure of the display panel is improved.

### Example 8

Embodiment 8 of the present invention provides a terminal. The terminal can be implemented in various forms. For example, the terminal described in the present invention may include terminals with communication function, for example, a mobile phone, a smart phone, a notebook computer, a digital broadcast receiver, a FDA (personal digital assistant), a PAD (tablet computer), a PMP (portable multimedia player), a navigation device, and the like.

In this embodiment, the terminal includes the polarization grating 100 described above. Of course, the structure of the display module is not limited thereto. Thus, the polarization section 22 and the light-shielding section 21 are fabricated on one component, and the compactness of the structure of the display panel is improved.

The detailed description of the specific embodiments of the present invention has been described above. Although some embodiments have been shown and described, it will be understood by those skilled in the art that the principle and spirit of the present invention can be understood without departing from the scope defined by the claims and their equivalents. Under the circumstances, these embodiments can be modified and improved, and these modifications and improvements should also fall within the scope of the present invention.

What is claimed is:

1. A manufacturing method for a polarization grating having a light-shielding layer, comprising:
forming a metal layer on a substrate;
forming a shielding layer on the metal layer, wherein the shielding layer includes a light-shielding pattern layer and a polarization grating pattern layer; and
etching the metal layer 20 according to the shielding layer to form a polarization grating, wherein the polarization grating includes a polarization section and a light-shielding section directly connected to the polarization section.

2. The manufacturing method for a polarization grating having a light-shielding layer according to claim 1, wherein the light-shielding pattern layer and the polarization grating pattern layer are formed in a same process.

3. The manufacturing method for a polarization grating having a light-shielding layer according to claim 2, wherein the step of forming a shielding layer on the metal layer comprises steps of:
forming an imprint adhesive layer on the metal layer; and
using an imprint template corresponding to the light-shielding pattern layer and the polarization grating pattern layer to perform a transfer process to the imprint adhesive layer in order to form the shielding layer.

4. The manufacturing method for a polarization grating having a light-shielding layer according to claim 2, wherein the step of forming a shielding layer on the metal layer comprises steps of:
forming a photoresist layer on the metal layer; and
using a mask plate corresponding to the shielding layer to utilize a lithography process to the photoresist layer in order to form the shielding layer.

5. The manufacturing method for a polarization grating having a light-shielding layer according to claim 1, wherein
the light-shielding section includes multiple light-shielding blocks arranged as a matrix, at least one first grating bar extending along a column direction is disposed between adjacent two columns of the light-shielding blocks, at least one second grating bar extending along the column direction is disposed between two adjacent light-shielding blocks in each column of the light-shielding blocks, and the polarization section includes multiple first grating bars and multiple second grating bars.

6. A polarization grating having a light-shielding layer, comprising:
a polarization section; and
a light-shielding section directly connected to the polarization section.

7. The polarization grating having a light-shielding layer according to claim 6, wherein the light-shielding section includes multiple light-shielding blocks arranged as a matrix, at least one first grating bar extending along a column direction is disposed between adjacent two columns of the light-shielding blocks, and at least one second grating bar extending along the column direction is disposed between two adjacent light-shielding blocks in each column of the light-shielding blocks.

8. The polarization grating having a light-shielding layer according to claim 6, wherein the light-shielding section includes multiple light-shielding blocks 21a arranged as a matrix, and the polarization section includes multiple grating bars arranged separately, and each light-shielding block is located on at least one of the grating bars.

9. The polarization grating having a light-shielding layer according to claim 6, wherein the light-shielding section and the polarization section are formed in a same process.

10. The polarization grating having a light-shielding layer according to claim 6, wherein the light-shielding block has a rectangular shape, and the light-shielding section and the polarization section are made of a metal material.

11. The polarization grating having a light-shielding layer according to claim 6, wherein a thickness of the polarization section is 20 nm˜3000 nm, a width of the grating bar of the polarization section is 30 nm˜100 nm, and a gap between adjacent two grating bars is 30 nm˜100 nm.

12. A display panel; comprising:
an array substrate and a polarization grating having a light-shielding layer;
wherein the polarization grating having a light-shielding layer is disposed on the array substrate, the light-shielding section is right opposite to a thin-film transistor of the array substrate;
wherein the polarization grating having a light-shielding layer is a polarization grating having a light-shielding layer manufactured by the manufacturing method in claim 1.

13. The display panel according to claim 12, wherein the light-shielding pattern layer and the polarization grating pattern layer are formed in a same process.

14. The display panel according to claim 13, wherein the step of forming a shielding layer on the metal layer comprises steps of:
forming an imprint adhesive layer on the metal layer; and
using an imprint template corresponding to the light-shielding pattern layer and the polarization grating pattern layer to perform a transfer process to the imprint adhesive layer in order to form the shielding layer.

15. The display panel according to claim 13, wherein the step of forming a shielding layer on the metal layer comprises steps of:
forming a photoresist layer on the metal layer; and
using a mask plate corresponding to the shielding layer to utilize a lithography process to the photoresist layer in order to form the shielding layer.

16. The display panel according to claim 12, wherein the light-shielding section includes multiple light-shielding blocks arranged as a matrix, at least one first grating bar extending along a column direction is disposed between adjacent two columns of the light-shielding blocks, at least one second grating bar extending along the column direction is disposed between two adjacent light-shielding blocks in each column of the light-shielding blocks, and the polarization section includes multiple first grating bars and multiple second grating bars.
